(19) United States
(12) Patent Application Publication
(10) Pub. No.: US 2026/0142665 A1
(43) Pub. Date: May 21, 2026

(54) CASCADED MULTI-LOOP PHASE LOCKED LOOP (PLL) CLOCK SYNCHRONIZER TOLERANT TO FAILURE OF INTERMEDIATE LOOPS

(71) Applicant: Shaoxing Yuanfang Semiconductor Co., Ltd., Shaoxing (CN)

(72) Inventors: Akash Gupta, Bangalore (IN); Sandeep Sasi, Bangalore (IN); Ankit Seedher, Bangalore (IN); Rakesh Kumar Gupta, Bangalore (IN); Raja Prabhu J, Bangalore (IN); Jeevabharathi G, Bangalore (IN); Yash Pamnani, Bangalore (IN)

(21) Appl. No.: 19/340,943

(22) Filed: Sep. 26, 2025

(30) Foreign Application Priority Data
Nov. 19, 2024 (IN) 202441089641

(51) Int. Cl. H03L 7/107; H03L 7/099

(52) U.S. Cl. CPC H03L 7/107; H03L 7/0992

(57) ABSTRACT

A cascaded multi-loop Phase-Locked Loop (CMPLL) includes a primary loop and multiple secondary loops according to a hierarchy. The primary loop is highest in the hierarchy and each of the secondary loops is completed by components of loops higher in the hierarchy. Each loop at a lower level provides a corresponding correction signal to correct any drift from a specification frequency of a respective loop at one or more of the higher levels. The CMPLL further includes a set of bypass circuits. Each bypass circuit is coupled between a first loop and a second loop located at least one skip-level in the hierarchy, and propagates a substitute signal as the corresponding correction signal from the first loop to the second loop when a loop at the skip-level is inoperative.

### PRIORITY CLAIM

The instant patent application is related to and claims priority from the co-pending India provisional patent application entitled, “Multi Loop PLL based Frequency Translator/Jitter Attenuator/Network Synchronizer”, Serial No.: 202441089641, Filed: 19, Nov. 2024, Attorney docket no.: AURA-369-INPR, which is incorporated in its entirety herewith to the extent not inconsistent with the description herein.

### BACKGROUND

### Technical Field

Embodiments of the present disclosure relate generally to clock synchronizers, and more specifically to cascaded multi-loop phase locked loop (PLL) clock synchronizer tolerant to failure of intermediate loops.

### Related Art

A multi-loop Phase-Locked Loop (PLL) refers to a PLL which employs multiple loops in generating an output clock synchronized to an input clock. A primary loop of the multi-loop PLL (MPLL) generally contains sufficient components to generate an output clock from the input clock, with the other loops being designed to provide performance, stability, etc., by appropriate corrections.

A cascaded MPLL (CMPLL) is a type of MPLL in which loops are cascaded hierarchically such that the primary loop is corrected by a next (lower) loop in the hierarchy, which in turn is corrected by the next (lower) loop in the hierarchy. Each loop of the cascaded MPLL is constituted of (and thus completed by) components in the loop(s) of higher level(s).

One challenge in such CMPLLs is potential failure of operation of one or more of the intermediate loops. When such failure occurs, the primary loop may either lose the benefit of corrections by one or more of the lower-level loops, or the output clock of the CMPLL may at least temporarily deviate from its desired frequency even if the corrections were propagated to the primary loop. Aspects of the present disclosure are directed to addressing such challenges.

### BRIEF DESCRIPTION OF THE VIEWS OF DRAWINGS

Example embodiments of the present disclosure will be described with reference to the accompanying drawings briefly described below.

FIG. 1 is a block diagram illustrating the details of a cascaded multi-loop phase locked loop (CMPLL), in an embodiment of the present disclosure.

FIG. 2 is a diagram used to illustrate the manner in which changes in the frequency of an output clock of a CMPLL due to clock drift of a source clock are nullified, in an embodiment of the present disclosure.

FIG. 3 is a block diagram illustrating the details of a cascaded multi-loop phase locked loop (CMPLL), in another embodiment of the present disclosure.

FIG. 4 is a block diagram illustrating the details of a CMPLL in yet another embodiment of the present disclosure.

FIG. 5 is a block diagram of an example system incorporating a CMPLL implemented according to various aspects of the present disclosure.

In the drawings, like reference numbers generally indicate identical, functionally similar, and/or structurally similar elements. The drawing in which an element first appears is indicated by the leftmost digit(s) in the corresponding reference number.

### DETAILED DESCRIPTION

### 1. Overview

A cascaded multi-loop Phase-Locked Loop (CMPLL) provided according to an aspect of the present disclosure includes a primary loop and multiple secondary loops according to a hierarchy. The primary loop is highest in the hierarchy and each of the secondary loops is completed by components of loops higher in the hierarchy. Each loop at a lower level provides a corresponding correction signal to correct any drift from a specification frequency of a respective loop at one or more of the higher levels. The CMPLL further includes a set of bypass circuits. Each bypass circuit is coupled between a first loop and a second loop located at least one skip-level in the hierarchy, and propagates a substitute signal as the corresponding correction signal from the first loop to the second loop when a loop at the skip-level is inoperative.

Several aspects of the present disclosure are described below with reference to examples for illustration. However, one skilled in the relevant art will recognize that the disclosure can be practiced without one or more of the specific details or with other methods, components, materials and so forth. In other instances, well known structures, materials, or operations are not shown in detail to avoid obscuring the features of the disclosure. Furthermore, the features/aspects described can be practiced in various combinations, though only some of the combinations are described herein for conciseness.

### 2. Cascaded Multi-loop Phase Locked Loop

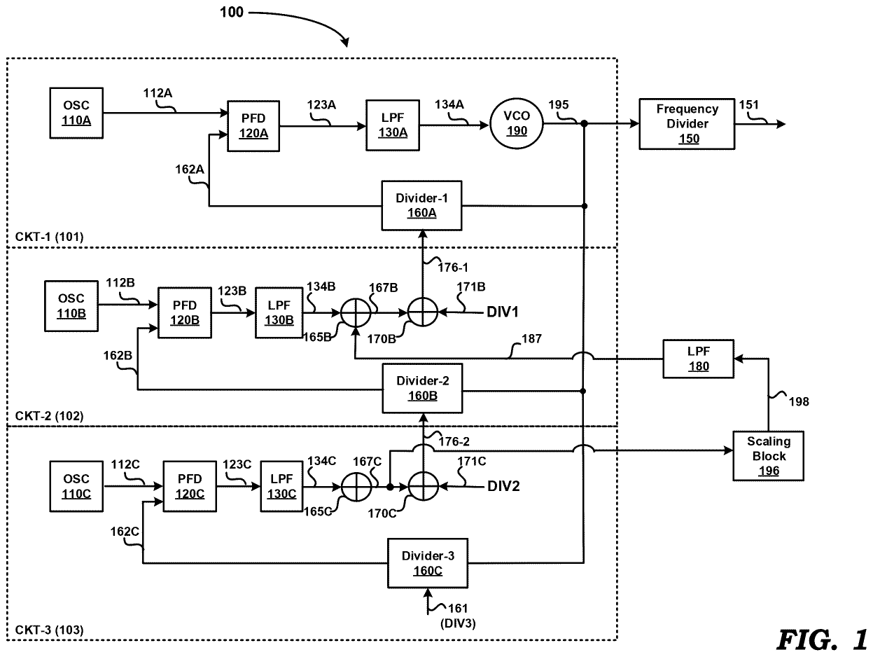

FIG. 1 is a block diagram illustrating the details of a cascaded multi-loop phase locked loop (CMPLL), in an embodiment of the present disclosure. CMPLL 100 is shown containing oscillators 110A-110C, phase frequency detectors (PFD) 120A-120C, low-pass filters (LPF) 130A-130C, LPF 180, voltage-controlled oscillator 190, frequency dividers 160A (divider-1), 160B (divider-2), 160C (divider-3) and 150, adders 165B, 165C, 170B and 170C and scaling block 190B. Dividers receiving correction from other loops are typically fractional-N dividers with an associated delta sigma modulator for frequency synthesis.

CMPLL 100 is indicated as having three portions, namely CKT-1 (101), CKT-2 (102) and CKT-3 (103), each respectively made of the blocks inside the corresponding dashed boxes. CKT-1 (101) represents a phase locked loop (PLL) that is referred to herein as a primary loop (loop-1). The combination of CKT-1 (101) and CKT-2 (102) represents a ‘secondary loop’ (loop-2) and the combination of CKT-1 (101), CKT-2 (102) and CKT-3 (103) represents another ‘secondary loop’ (loop-3). The secondary loops may be viewed as ‘cascaded loops’. The loops together form a hierarchy, with the primary loop (loop-1) being at the highest level (top) of the hierarchy, loop-2 being immediately lower to loop-1, and loop-3 being immediately lower to loop-2.

As noted above, each secondary loop is completed by components of loops higher in the hierarchy. Such an observation holds even if one of the intermediate loops fails and the corresponding bypass circuit is operational. For example, assuming that CKT-3 (103) fails, then loop 4 would contain components of CKT- 2 and CKT- 1 (but not those of CKT- 3) due to the corresponding bypass path.

It is noted here that, in general, the frequency-stability and/or accuracy of the clock sources generating clocks 112A, 112B and 112C are in increasing order. Thus, clock 112A is least accurate/frequency-stable, clock 112B is more frequency-stable/accurate than clock 112A, and so on. Further, one or more of the outer (i.e., secondary) loops may receive a clock generated externally in the network, as illustrated with respect to an alternative embodiment below.

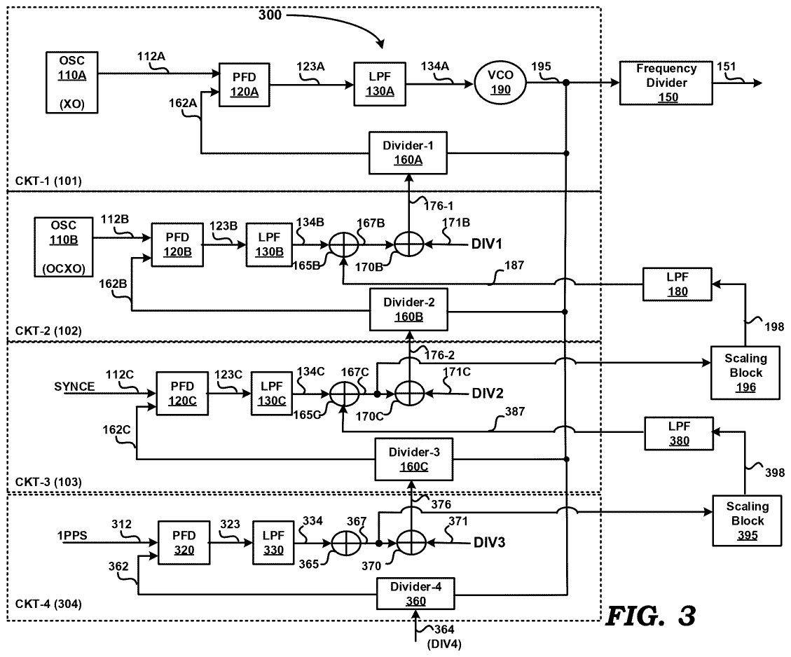

Some alternative embodiments (e.g., as in FIG. 3) may contain more secondary loops successively lower in the hierarchy. In an embodiment of the present disclosure, CKT-1 is an analog PLL, and CKT-2 and CKT-3 are each implemented using digital circuits/blocks except for oscillators 120B and 120C. However, in other embodiments, CKT-1 (101), CKT-2 (102) and CKT-3 (103) can be implemented in a different manner. The combination of blocks 180 and 190B represents a ‘bypass circuit’.

In some embodiments, one or more of oscillators 110A, 110B and 110C (together referred to as oscillators 110) may not be implemented integral to CMPLL 100 (as an integrated circuit), and their clocks 112A-112C may instead be received from an external source.

Referring to CKT-1 (101), oscillator 110A generates a clock on path 112A. PFD 120A receives clock 112A and a feedback clock from divider-1 (160A) on path 162A, and operates to generate, on path 123A, an error signal indicating a phase difference between clocks 112A and 162A. LPF 130A is a low-pass loop filter. LPF 130A (as well as one or more of the other LPFs noted in the description herein) may be implemented differently from a traditional low-pass filter with constant DC gain at frequencies below the corner (cut-off) frequency. Instead, LPF 130A may be implemented as a (Proportional+Integral) (PI) path filter that accordingly filters error signal 123A to generate a filtered output (a voltage) on path 134A.

VCO 190 generates an output clock on path 195 with a frequency that is determined by the voltage on path 134A. VCO 190 may be implemented using inductors and capacitors (LC) when low jitter is desirable in output clock 195. For more relaxed jitter requirements, VCO 190 may be implemented using a ring oscillator. Divider-1 (160A) divides the frequency of output clock 195 by a number/digital value received as input on path 176-1 to generate feedback clock 162A. The number on path 176-1 is the sum of a fixed value (DIV1) provided on path 171B by user input or other suitable means and the number/digital value on path 167B which can vary with time based on factors that are further described below.

As noted above, CKT-1 is a PLL whose output clock 195 has a frequency that is a multiple (N)

of the frequency of clock 112A, with N being the number received on path 176-1. Any changes to the number N on path 176-1 are typically effected at the end of the present division by divider-1. In other words, divider-1 typically applies the divisor N at the completion of the present divide cycle. More specifically, the value 176-1 is a fraction greater than 1, say N.M. Divider-1 contains a delta-sigma modulator that receives the value N.M, generates/computes a corresponding sequence of integer divisors, and divides clock 195 sequentially by each integer value of the sequence of integer divisors such that the frequency of clock 195 averages to the desired multiple (fractional multiple, such as (N.M)x), as is well known in the relevant arts. Each of the blocks of CKT-1 can be implemented in a known way.

Referring to CKT-2 (102), oscillator 110B generates a clock on path 112B. PFD 120B receives clock 112B and a feedback clock from divider-2 (160B) on path 162B, and operates to generate, on path 123B, an error signal indicating a phase difference between clocks 112B and 162B. LPF 130B is a low-pass loop filter that accordingly filters error signal 123B to generate a filtered output (in the form of a number/digital value) on path 134B. Adder 165B adds the digital values on paths 134B and 187, and forwards the sum on path 167B. Adder 170B adds the digital values on paths 167B and 171B (DIV1), and forwards the sum on path 176-1.

Divider-2 (160B) divides the frequency of output clock 195 by a number/digital value received as input on path 176-2 to generate feedback clock 162B. The number on path 176-2 is the sum of a fixed value (DIV2) provided on path 171C by user input or other suitable means and the number on path 167B which can vary with time based on factors that are further described below. The combination of CKT-1 and CKT-2 represents a secondary loop (loop-2) formed by the blocks ‘PFD 120B-LPF 130B-adder 165B-adder 170B-divider-1 160A-PFD 120A-LPF 130A VCO 190-divider-2 160B’.

Referring to CKT-3 (103), oscillator 110C generates a clock on path 112C. PFD 120C receives clock 112C and a feedback clock from divider-3 (160C) on path 162C, and operates to generate, on path 123C, an error signal indicating a phase difference between clocks 112C and 162C. LPF 130C is a low-pass loop filter that accordingly filters error signal 123C to generate a filtered output (in the form of a number/digital value) on path 134C. Adder 165C is shown in FIG. 1 for consistency in structure of CKT-3 with CKT-2, but does not perform any addition. Instead, in the embodiment of FIG. 1, adder 165C merely forwards digital value 134C on path 167C.

Adder 170C adds the digital values on paths 167C and 171C (DIV2), and forwards the sum on path 176-2. Divider-3 (160C) divides the frequency of output clock 195 by a number/digital value received as input on path 161 (DIV3) to generate feedback clock 162C. DIV3 is a fixed value provided by a user or other suitable means. The combination of CKT-1, CKT-2 and CKT-3 represents another secondary loop (loop-3) formed by the blocks ‘PFD 120C-LPF 130C-adder 165C-adder 170C-divider-2 160B-PFD 120B-LPF 130B-adder 165B-170B-divider-1 160A-PFD 120A-LPF 130A-VCO 190-divider-3 160C’.

Scaling block-1 (195) performs a scaling operation by multiplying the value on path 167C by the factor (DIV1/DIV2), and forwards the scaled value on path 198 to low pass filter (LPF) 180. LPF 180 has a bandwidth BW2 and accordingly filters the input on path 198. LPF 180 forwards the filtered values on path 187 to adder 165B of CKT-2. The use of LPF 180 is optional. Thus, in another embodiment, LPF 180 is not implemented and the output of scaling block-1 195 is directly provided to adder 165B.

Frequency divider 150 divides the frequency of output clock 195 and provides a final clock on

path 151. Each of frequency dividers 160A-160C and 150 is implemented as a fractional divider (i.e. divide by a fraction greater than one) employing, for example, delta-sigma modulators well known in the relevant arts. Alternatively, some or all of those dividers may be implemented as integer dividers (i.e., divide by an integer).

Oscillators 110A, 110B and 110C are selected/designed to generate clocks 112A, 112B and 112C respectively (generically referred to herein as ‘source clock's 110) with desired frequencies per the specification/design of CMPLL 100. Alternatively, one or more of clocks 110 can be received (with a known frequency) from external sources. The desired frequencies per design or specification are referred to herein as ‘specification frequencies’. Accordingly, each of loops loop-1, loop-2 and loop-3 may also be viewed as having the corresponding ‘specification frequency’.

DIV1 is set to a value such that the frequency of output clock 195 is equal to the product of DIV1 and the frequency of clock 112A.

Similarly, DIV2 and DIV3 are set to values such that the frequency of output clock 195 is (also) equal to the product (DIV2*frequency of clock 112B) and the product (DIV3*frequency of clock 112C) respectively, wherein the symbol ‘*’ is the multiply operator. As an illustration, oscillators 110A, 110B and 110C may be designed to generate respective clocks 112A, 112B and 112C having frequencies 96 MHz (mega Hertz), 10 MHz and 1 MHz. In such an example, loop-1, loop-2 and loop-3 may be viewed as having respective specification frequencies of 96 MHz, 10 MHz and 1 MHz respectively, and in steady-state operation of CMPLL 100, each of the products (DIV1*96 MHz), (DIV2*10 MHz) and (DIV 3*1 MHz) equals the (desired) frequency of output clock 195.

The arrangement of loops in CMPLL 100 enables a loop lower in the hierarchy to correct for changes in the frequency (fo) of output clock 195 due to oscillator drift of one or more loops higher in the hierarchy. Thus, ignoring signals 176-2 and 187, the coupling via path 176-1 between CKT-2 and CKT-1 enables CKT-2, or more precisely, loop-2 to correct for any change (or drift) in the frequency of output clock 195 from its desired value due to drift in clock 112A. For example, assuming CMPLL 100 has reached steady-state operation (after power-up), each of the products (DIV1*96 MHz), (DIV2*10 MHz) and (DIV3*1 MHz) equals the (desired) frequency of output clock 195.
Denoting, the (desired) frequency of output clock 195 as fo:

$$fo = DIV 1 * 96 MHz = DIV 2 * 10 MHz = DIV 3 * 1 MHz \qquad Equation 1$$

In general,

$$fo = DIV 1 * ( freq - 112 A ) = DIV 2 * ( freq - 112 B ) = DIV 3 * ( freq - 112 C ) \qquad Equation 2$$

wherein, freq-112A is the frequency of clock 112A,
   freq-112B is the frequency of clock 112B, and
   freq-112C is the frequency of clock 112C.

From the steady-state condition, if the frequency of oscillator 110A were to change (for example, due to ‘oscillator drift’ because of temperature-changes and/or other reasons), then fo would change. As a result, the phase/frequency of feedback clock 162B would change and therefore, loop-2 would react to such change. Assuming that there is no change in the frequency of clock 112B, the value on path 167B, and therefore path 176-1, would change from its previous steady-state’ value, with the change representing a correction provided by loop-2 to loop-1 via divider-1.

Since frequency of clock 112B and the value of DIV2 have not changed, the ‘correction’ on path 176-1 would operate to bring fo back to its desired value. In general, if the ‘frequency-stability’ of the clock source that generates clock 112B is better (greater) than that of the clock source that generates 112A, then the frequency-stability of output clock fo would be as good as that of the source that generates clock 112B. In other words, frequency fo is termed as ‘tracking’ the frequency of clock 112B.

In a manner similar to that noted above, the coupling via path 176-2 between CKT-3 and CKT-2 enables loop-3 to correct for any drift in the sources of clock 112B and 112A. Thus, each loop at a lower level provides a corresponding correction signal to correct any drift from a specification frequency of one or more loops at higher levels. This would, in general, be true if the frequency-stability of the source that generates clock 112C is greater than that of the source that generates clock 112B, and the source that generates clock 112B is greater than that of the source that generates clock 112A.

In the embodiments described herein, the bandwidths (BW) of loops loop-1, loop-2 and loop3 are in descending order. That is, BW of loop-1 is greater than that of loop-2, and BW of loop-2 is greater than that of loop-3. The respective loop bandwidths are substantially determined by the bandwidths of LPFs 130A, 130B and 130C respectively. In some other alternative embodiments, the relation between the loop bandwidths can be different. Also, the phase jitter of source clocks 112A, 112B and 112C are in increasing order of magnitude. That is, phase jitter of clock 112A is smaller than that of clock 112B, whose phase jitter is smaller than that of clock 112C.

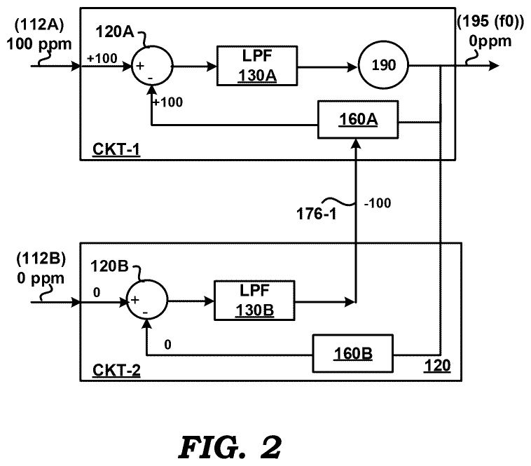

FIG. 2 illustrates a frequency-correction example. The clock frequencies noted in FIG. 2

are indicated in terms of ppm (parts per million). As used herein, +/−X ppm means a frequency that is away from a specification frequency by X ppm, i.e., X ppm above the specification frequency or X ppm below the specification frequency. To illustrate with an example, assuming the specification frequency is 100 Mega Hertz (MHz), a clock with a frequency expressed as −100 ppm would have a frequency [100*(1 - (100/1000000))] MHz, i.e., 99.99 MHz (Mega Hertz). In the example of FIG. 2, clock 112A is +100 ppm and clock 112B is 0 ppm.

Clock 112A being at +100 ppm can imply that clock 112A was 0 ppm initially (say upon first deployment of CMPLL 100 or upon power ON, but drifted to +100 ppm due to temperature change during operation. Alternatively, clock 112A being at +100 ppm can imply that clock 112A (or its source) inherently has a frequency inaccuracy. Either way, the frequency drift or frequency inaccuracy of clock 112A would cause output clock fo (195) to also have a corresponding frequency error and would therefore be +100 ppm without correction (176-1) from the next outer loop (CKT-2+CKT-1).

Therefore, the output of divider 160B would also be +100 ppm immediately prior to the beginning of correction—i.e., when the outer loop starts to react, which would cause the output of (PFD 120B+LPF 130B) to generate a correction via signal 176-1 (shown to be −100 in steady state in FIG. 2). As a result, in steady-state, the divisor in 160A would be correspondingly changed (reduced in this example) so as to cause the output of divider 160A to be +100 ppm. This, in turn, would cause the output of PFD 120A, and therefore f0, to have no frequency-error content in steady-state.

Loop-3 can similarly correct for frequency errors in fo due to errors/drift in one or more of clocks 112A and 112B.

As noted above, failure of operation of an intermediate loop can prevent the primary loop from obtaining (and therefore using) the corrections from one or more of the lower-level loops, or even if made available for use via a direct path (not shown) would cause a disturbance (frequency and phase changes) in output clock 195. In the 3-loop example of FIG. 1, in the absence of scaling block 195 and LPF 180 and the corresponding ‘bypass path’ so formed, if loop-2 were to fail, loop-1 would lose the corrections from loop-3 altogether (as for example, if there is a failure of oscillator 110B, loss of clock 112B, failure of PFD 120B, divider 160B or break (electrical disconnection of) the corresponding paths to/from these blocks).

Alternatively, even if the corrections on path 176-2 were directly made available to loop-1 (to divider 160A, for example, by means of a corresponding path (not shown) that can be switched ON and OFF, the corrections would introduce a transient on output clock 195, thereby causing the frequency and phase of output clock to change from their steady-state values prior to the application of the correction from loop-3, as explained further below.

According to an aspect of the present disclosure, corrections from loop-3 are available to loop-1 even if loop-2 were to fail. Furthermore, the corrections are modified before being provided to loop-1 and thereby enable application of the corrections to loop-1 without causing any (or at least any substantial) disturbance (hit) in the frequency or phase of output clock 195. Such a capability is achieved by implementing a bypass path from node 167C to node 187 containing scaling block 195 and LPF180. The operation of the bypass path is described next.

### 3. Bypass Path

Before describing the operation of the bypass path, certain features of the loops in the event of their failure are now described briefly. Each of CKT-1, CKT-2, CKT-3 and CKT-4 contains a loss-of-clock detection circuitry connected to receive the corresponding source clock, that monitors for presence/occurrence of proper clock cycles of the respective clocks 112A-112C and 312. Upon loss/failure of the corresponding source clock, the detection circuitry signals a ‘loss-of-clock’ to the corresponding LPF, which causes the loop to operate in a holdover (HO) mode by freezing/holding the last-good value of its output (i.e., value immediately prior to loss/failure of the source clock).

Referring to CKT-2, for example, upon loss of clock 112B (or failure of oscillator 110B) or a break in connecting path 112B, loop-2 is designed to go into ‘holdover’ mode, with LPF 130B designed to hold the last-known good/correct value on path 134B. Therefore, one input (value 134B) to adder 165B is fixed and constant. The other input is received through the bypass path, i.e., path 167C-scaling block 195-198-LPF 180-187. In an embodiment, scaling block 195 is designed to multiply the value on path 167C by the ratio DIV1/DIV2. The resulting product is low-pass filtered by LPF 180 and is provided as input to adder 165B via path 187.

In an alternative embodiment, the loss-of-clock detection circuitry is implemented to receive the output of the respective PFDs (rather than the source clocks). In such an embodiment, the loss-of-clock detection circuitry would be implemented differently from a clock-cycle counter (as when implemented to receive only the source clock). For example, in such an embodiment, the detection circuitry could be implemented to monitor the widths of the output pulses of the corresponding PFD. If the pulses deviate from the range of expected widths, the detection circuitry infers either a loss-of-clock or a fault in the PFD. In either case, the detection circuitry signals a ‘loss-of-clock’ to the corresponding LPF, which causes the loop to operate in a holdover (HO) mode by freezing/holding the last-good value of its output.

Failure of loop-2 can occur due to the reasons noted above. Failure of a loop implies that the correction from that loop are either stopped from being updated or are incorrect or unreliable. Thus, failure of loop-2 implies that the value(s) on path 176-1 are no longer available or are incorrect or unreliable.

With all of CMPLL 100 operating normally and having reached steady-state operation with output clock 195 being provided at the desired frequency, when failure of loop-2 occurs, the values on path 176-2 (and therefore corrections from loop- 3) to loop-2 via divider-2 160B are no longer effective. Hence, these corrections cannot propagate via loop-2 to loop-1 (via path 176-1).

However, due to the bypass path, the values on path 167C are propagated to adder 165B after scaling in scaling block 195 and filtering in LPF 180. The scaling in block 195 scales the values on path 167C by a factor DIV1/DIV2 (wherein, ‘/’ represents the division operator). Such scaling is required since the corrections (via path 176-2) from loop-3 to loop-2 must now go from loop3 to loop-1 (via the bypass path and eventually through 176-1). Since loop-1 operates with a clock source (oscillator 110A or external clock received directly on path 112A) whose frequency is different from that of the clock source of loop-2 (which operates with oscillator 110B or external clock received directly on path 112B), the corrections from loop-3 to loop-1 (provided by the bypass path) need to be modified (scaled, here multiplied) by a factor equal to frequency of clock 112B/frequency of clock 112A), or DIV 1/DIV2. From equation 2 above,

$$fo = DIV 1 * ( freq - 112 A ) = DIV 2 * ( freq - 112 B ) = DIV 3 * ( freq - 112 C ) \qquad Equation 3$$

$$Therefore , DIV 1 / DIV 2 = freq - 112 B / freq - 112 A .$$

Since the corrections from loop-3, which were previously sent to loop-2, now need to be provided to loop-1, the corrections need to be scaled by a factor freq-112B/freq-112A, which is also equal to DIV 1/DIV2 as in Equation 3 above. The scaling noted above is illustrated below with an example.

The BW of LPF 180 is designed to be equal to that of loop-2. It is noted here that, typically, LPF 130B determines BW of loop-2 partially. Additionally, other factors such as reference clock 112B's frequency, PFD 120B's gain, gain from Divider-1's input to VCO output (195) also determine BW of loop-2). Therefore, corrections on path 167C, which would bypass the low-pass filtering provided by loop-2 when passing through the bypass path instead, are low-pass filtered. Such low-pass filtering using LPF180 may be necessary when it is desired that the jitter specifications of output clock 195 are not degraded when loop-2 fails and the bypass path provides the corrections.

However, if such degradation in jitter-specification of output clock 195 is acceptable, LPF 180 may be omitted and the output of scaling block 195 is directly provided to adder 165B. Effectively, the replica LPF (e.g., 180 in FIG. 1) in a bypass path is used to match the transfer function through the respective loop (e.g., loop-2 in FIG. 1) to maintain the desired Jitter Attenuator Transfer characteristics of CMPLL 100.

Due to the appropriate scaling of the correction 167C by scaling block 195, the corrections 167C when applied to adder 165B, and thus to loop- 1 will not cause an abrupt jump or disturbance/transient in output clock 195. Therefore, the corrections, if any, correct the frequency of output clock 195 with zero or minimal hit (disturbance) on the phase and/or frequency of output clock 195 even upon loss of an intermediate source clock or in general, failure of the intermediate loop. When CMPLL 100 has more than three loops, failure of any one or more intermediate loops allows the primary loop to receive and make use of corrections from an operative loop lower down in the hierarchy than the lowest of the failed intermediate loops, without causing a hit/disturbance in output clock 195.

It may be observed that, when loop-2 is operational, the corrections via the bypass path on path 187 are concurrently applied with the corrections via path 176-2. The manner in which the corrections change the output clock's frequency is briefly illustrated next with an example. Assuming the bypass path containing scaling block 195 and LPF 180 were not present, from Equation 2 above, and from/following steady-state condition of output clock 195, a 10 ppm change in the divisor applied by divider 160B will cause a 10 ppm change in fo (195). A 10 ppm change in the divisor of divider 160B corresponds to [(X+DIV2)/DIV2]*1000000], wherein ‘X refers to the value on path 167C.

From Equation 2, the change in the divisor of divider 160A should also equal 10 ppm. Thus, [(Z+DIV1)/DIV1]*1000000] should equal [(X+DIV2)/DIV2]*1000000], wherein, ‘Z’ refers to the value on path 134B. If loop-2 were to fail, the value Z would have to be provided instead at node 187 (both the node 187 and the value there are referred to as ‘W’ for convenience) by the bypass path containing scaling block 195 and LPF 180. From the above relations, [(X+DIV2)/DIV2] * 1000000]=[(W+DIV1)/DIV1]*1000000]. Therefore, X/DIV2=W/DIV1, i.e., W=X*(DIV1/DIV2).

The scaling factor (DIV1/DIV2) is provided by scaling block 195 as noted above. The scaling in the bandpass region of LPF 180 is 1. When the bypass path is present, corrections (in response to change fo due to clock drift of clocks 112A and/or 112B) are generated by loop-2 on both of paths 167C and 187. Since all the change need in Z is provided by W, the value at Z does not change in response to change in fo.

It may be appreciated that the simultaneous application of the corrections via the bypass path even when loop-2 is operational ensures that in the event of failure of loop-2, LPF 130 would hold/freeze its last known good value on path 134B. Since corrections 187 from the bypass path have continuously been applied to adder 165B, corrections 187 immediately following failure of loop-2 will not represent a large step-jump immediately following failure. In other words, corrections 187 would at best be changing only by very small values at, and immediately following failure of loop-2, and would thus be ‘seamless’.

As a result, output clock 195 does not manifest a hit or disturbance (i.e., sudden change in frequency and phase) that could otherwise linger for a long-time rendering output clock 195 (or clock 151) potentially unusable at its destination. Had corrections 187 be applied to adder 165B only upon or after failure of loop-2, then it is possible that the correction could be a large step correction which could cause an unacceptable hit/disturbance in output clock 195, potentially rendering clock 151 unusable.

Due to finite precision used in representing DIV1/DIV2 in scaling block 195, a corresponding quantization error may be introduced in the bypass path. However, such quantization error is compensated or removed during normal operation when no loop fails (here, when loop-2 is still operative). The application of the output of the bypass path to adder 165B even when loop-2 is operative would cause the output 134B to have values which would compensate for the quantization error.

Upon failure of loop-2, loop-2 goes into holdover mode and LPF 130B would hold the last value (or historical average) of 134B, which would contain/include the compensation for the quantization error. This is another benefit of operating the bypass path simultaneously even when the corresponding intermediate loop (here loop-2) is operative normally.

The output/correction (here187) from a bypass path may be viewed as a ‘substitute’ signal to the corresponding correction signal (here 167C) from loop-3 to loop-2 when loop-2 is inoperative. It may be observed that the substitute signal is a scaled value of the corresponding correction signal. Substitute signal 187 is thus provided from loop-3 to loop-1, bypassing loop-2. Thus, loop-1 is said to be one ‘skip-level’ (corresponding to loop-2) higher than loop-3 in the hierarchy.

While the embodiment shows all bypass paths operating with a single skip-level, it should be appreciated that alternative embodiments can optionally have bypass paths with more than one skip-level also. Such multiple skip-levels may be particularly suitable when a CMPLL has more (than 3) loops to account for situations when more than one intermediate adjacent loops fail.

In an embodiment, a CMPLL provided according to several aspects of the present disclosure is used in a network synchronization environment in telecommunication networks, as described next.

### 4. Network Synchronization

As is well-known in the relevant arts, telecommunication networks are used for transmitting and receiving data packets as well as other signals such as single-tone frequency signals. It is a general requirement in such networks is network synchronization, i.e., various (or all) portions and nodes of the network may all need to maintain time accurately (i.e., their clocks need to tick at the same rate). Accordingly, a master (time-keeper) station transmits current-time (time-of-day or TOD) to various nodes of the network, for example, via boundary stations to slave stations. One use of such TOD information is to time-stamp data packets at one or more nodes in the network as the data packets traverse the network from a source to destination.

One requirement for a phase locked loop (PLL) used in a telecommunication network (for example, in a slave station/node or boundary station/node) is as specified in the ITU-T standard G.8273.2. This standard requires the PLL to be able to generate an output clock to ‘track’ one or more of multiple grades of clocks with different levels of priority/transfer function. Four grades of clocks are specified by the standard, namely XO, OCXO, SYNCE, GPS/1 pps/PTP] in order of increasing frequency precision and frequency stability. XO, OCXO, SYNCE and GPS/1 pps/PTP respectively denote a clock generated by a crystal oscillator, an oven-controlled crystal oscillator, specified by the Synchronous Ethernet standard, and a 1 pulse-per-second signal/clock obtained using the Global Positioning System (GPS) or Precision Time Protocol.

The specification requires that if all the clocks are available, then the output clock of the PLL should track GPS/1 pps/PTP signal. If GPS/1 pps/PTP is lost, then the output clock should track SYNCE. If SYNCE is lost, then the output clock should track OCXO. If OCXO is lost, then the output clock should track XO. The term ‘track’ is used to mean ‘frequency stability should be substantially equal to that of’. In other words, frequency-drift in the input clock that is within the DPLL's BW is exactly tracked at the output clock.

Further, after a steady-state duration with all clocks available, if any clock is lost [except XO], then the output clock should have minimal phase/frequency transient/hit. Also, the different input/output jitter-attenuator phase transfer function has to be met.

FIG. 3 is a block diagram of a CMPLL clock synchronizer in another embodiment of the present disclosure. CMPLL 300. CPMLL 300 may be contained in a slave station/node or a boundary station/node of a telecommunication network, and is shown containing CKT-1, CKT-2, CKT-3, frequency divider 150, LPF 180, scaling block 195, CKT-4, LPF 380 and scaling block 395. CKT-1, CKT-2, CKT-3, frequency divider 150, LPF 180 and scaling block 195 are the same as shown in FIG. 1 except for the differences noted next, and their detailed description is not repeated again in the interest of conciseness.

Oscillator 110A is a crystal oscillator (XO). Oscillator 110B is an oven-controlled oscillator (OCXO). Oscillator 110C is not implemented, and a timing signal (SYNCE) according to the synchronous ethernet standard is received on path 112C. Divider-3 (160C) receives an input on path 376 (instead of path 161 as shown in FIG. 1). Adder 165C adds the values on paths 134C and 387, and provides the sum on path 167C.

Referring to CKT-4(304 ), a 1 PPS clock (GPS-derived), or alternatively, a PTP timing signal, is received on path 312. PFD 320 receives clock 312 and a feedback clock from divider-4 (360) on path 362, and operates to generate, on path 323, an error signal indicating a phase difference between clocks 312 and 362. LPF 330 is a low-pass loop filter that accordingly filters error signal 323 to generate a filtered output to generate a filtered output (in the form of a number/digital value) on path 334.

Adder 365 forwards the digital values on paths 334 to adder 367. It is noted that adder 365 need not be implemented, and path 334 can be directly connected to path 367. Adder 370 adds the digital values on paths 367 and 371 (DIV3 ), and forwards the sum on path 376. Divider-4 (360) divides the frequency of output clock 195 by a number/digital value (DIV4) received as input on path 364 to generate feedback clock 362. The number on path 364 is a fixed value (DIV4) provided by user input or other suitable means.

The combination of CKT-1, CKT-2, CKT-3 and CKT-4 represents another secondary loop (loop-4) formed by the blocks ‘PFD 320-LPF 330-adder 365-adder 370-divider-3 160C-PFD 120C-LPF 130C-adder 165C-adder 170C-divider-2 160B-PFD 120B-LPF 130B-adder 165B-adder 170B-divider-1 160A-PFD 120A-LPF 130A-VCO 190-divider-4 360’. Loop-4 is deemed to be the lowest loop in the hierarchy.

In the embodiments described herein, the bandwidths (BW) of loops loop-1, loop-2, loop-3 and loop-4 are in descending order. That is, BW of loop-1 is greater than that of loop-2, BW of loop-2 is greater than that of loop-3, and the BW of loop-3 is greater than that of loop-4. The respective loop bandwidths are substantially determined by the bandwidths of LPFs 130A, 130B, 130C and 330 respectively.

In some other alternative embodiments, the relation between the loop bandwidths can be different. In an embodiment, the frequencies of XO clock 112A and OCXO clock 112B are 94 Mega Hertz (MHz) and 10 MHz respectively. The frequencies of SYNCE and 1 PPS/PTP signals are respectively 1 MHz (or 8 kilo Hertz) and 1 Hz. The frequency accuracy and stability of the 4 source clocks are in the descending order: 1 PPS>SYNCE>OCXO>XO.

Also, the phase jitter of source clocks on respective paths 112A, 112B, 112C and 312 are in increasing order of magnitude. That is, phase jitter of XO clock on 112A is smaller than that of OCXO clock on 112B, whose phase jitter is smaller than that of SYNCE clock on 112C, whose phase jitter is smaller than that of 1 PPS/PTP clock on 312.

The operation of CKT-4 (and loop-4) is similar to that of the other intermediate loops except that it is larger and also the outermost/lowest loop in the hierarchy. Briefly, 1 PPS/PTP clock has the highest accuracy and frequency stability among the source clocks in FIG. 3. Loop-4 corrects any frequency drifts in output clock 195 (due to drifts in any of the other source clocks) by generating correction signals on path 367. The correction signals 367 change the divisor of divider 160C of loop-3, the change in turn causing a cascading effect of corrections via loop-2 and loop-1 and finally output clock 195, in a manner similar to that described above with respect to the CMPLL of FIG. 1.

The combination of scaling block 395 and LPF 380 represents another bypass path (BP-2). Scaling block 395 performs a scaling operation by multiplying the value on path 367 by the factor (DIV2/DIV3), and forwards the scaled value on path 398 to low pass filter (LPF) 380. LPF 380 has a bandwidth BW3 and accordingly filters the input on path 398. LPF 380 forwards the filtered values on path 387 to adder 165C of CKT-3.

The BW of LPF 380 is designed to be equal to that of loop-3 (which in turn is substantially determined by LPF 130C). The use of LPF 380 is optional. Thus, in another embodiment, LPF 380 is not implemented and the output of scaling block 395 is directly provided to adder 165C. Bypass path BP-2 operates in a manner similar to bypass path BP-1, except that BP-2 is used to bypass loop-3 in case of failure of loop-3, and the description is not provided here in the interest of conciseness.

CMPLL 300 conforms to the requirements of the ITU-T standard G.8273.2. Thus, CMPLL 300 is capable of tracking multiple grades of clocks with different levels of priority/transfer function., namely four grades of clocks XO, OCXO, SYNCE, GPS/1 pps/PTP in order of increasing frequency precision and frequency stability. Further, it may be verified based on the description provided thus far, that CMPLL 300 supports the following requirement of the standard noted above:
1) If all the clocks are available, then output clock 195 tracks GPS/ 1 pps/PTP clock/signal.
2) If GPS/1 pps/PTP clock is lost, then output clock 195 tracks SYNCE clock.
3) If SYNCE clock is lost, then output clock 195 tracks OCXO clock.
4) If OCXO clock is lost, then output clock 195 tracks XO clock.
5) After a steady-state duration with all clocks available, if any clock is lost [except XO], then output clock 195 has minimal phase/frequency transient/hit.
6) The different input/output jitter-attenuator phase transfer function are met.

The description is continued with respect to a CMPLL in yet another embodiment of the present disclosure.

### 5. Improving Hardware Implementation Efficiency

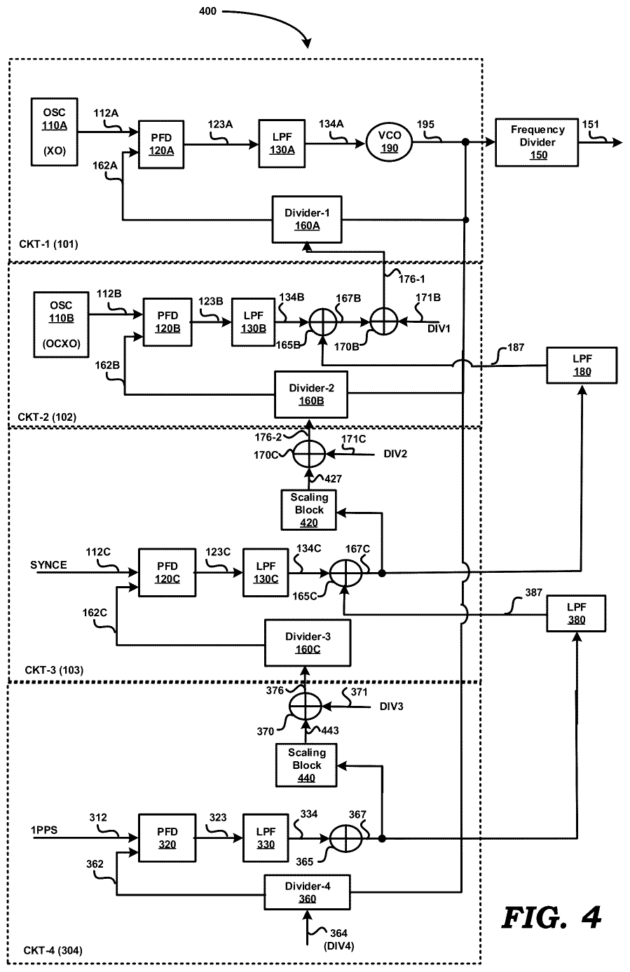

FIG. 4 is a block diagram of a CMPLL in another embodiment of the present disclosure. CMPLL 400 is shown there containing blocks CKT-1, CKT-2, CKT-3, CKT-4, frequency divider 150, LPF 380 and LPF 180. The blocks of CMPLL 400 numbered the same as those in FIG. 3 are as described above, and their description is not repeated in the interest of conciseness. Only the differences of CMPLL 400 from CMPLL 300 are noted below.

Scaling block 420 replaces scaling block 195 of FIG. 3, and is connected differently in CMPLL 400 as shown in FIG. 4. Scaling block 420 receives the value on path 167C, multiplies the value by a scaling factor (noted below), and forwards the product to adder 170C on path 427. LPF 180 directly receives the value on path 167C.

Scaling block 440 replaces scaling block 395 of FIG. 3, and is connected differently in CMPLL 400 as shown in FIG. 4. Scaling block 440 receives the value on path 367, multiplies the value by a scaling factor (noted below), and forwards the product to adder 370 on path 443. LPF 380 directly receives the value on path 367.

It may be observed that the only difference in CMPLL 400 from CMPLL 300 of FIG. 3 is in the two bypass paths, which now respectively contain only LPF 180 and LPF 380, and that the scaling block of a bypass path is now placed in the ‘direct correction’ path from a lower loop to the immediate higher loop. In an embodiment, scaling block 420 multiplies the value on path 167C by a factor DIV2/DIV1, and scaling block 440 multiplies the value on path 367 by a factor DIV3/DIV1.

The correction code (F) on path 167B in terms of ppm with respect to DIV1 is (F/DIV1*1000000). The correction code (G) on path 427 in terms of ppm with respect to DIV2 is G/DIV 2*1000000). Since the scaling in LPF 180 is 1, the correction H (in terms of ppm) at 167C equals F. Therefore, the required scaling factor (to scale H to G) in scaling block 420 is (DIV2/DIV1). Using a similar analysis, the scaling factor of scaling block 440 is DIV3/DIV1.

As an example, the output/correction (187) from a bypass path may be viewed as a ‘substitute’ signal to the corresponding correction signal (427) from loop-3 to loop-2 when loop-2 is inoperative. In this embodiment of the disclosure as well, it may be observed that a substitute signal is a scaled value of the corresponding correction signal. However, the scaling factor in the embodiment of FIG. 4 is different from that of FIG. 3. In the embodiment of FIG. 3, the scaling factor (e.g., DIV1/DIV2) applied to a correction signal to obtain the corresponding substitute signal is the ratio of the fixed divisor of the loop receiving the substitute signal to the fixed divisor of the failed loop. However, in the embodiment of FIG. 4, the scaling factor (e.g., [1/(DIV3/DIV1)]) applied to a correction signal to obtain the corresponding substitute signal is the inverse of the ratio of the fixed divisor of the loop transmitting the substitute signal to the fixed divisor of the primary loop.

One advantage of the implementation of FIG. 4 over that of FIG. 3 is that the hardware Implementation in FIG. 4 is more efficient in that it requires fewer interconnection paths and corresponding hardware blocks/resources in some of the paths. Specifically, at least for source clock frequencies noted above, and for fo of 96 MHz or greater, the divisors needed in dividers 160A, 160B, 160C and 360 are progressively larger. Therefore, in the implementation of FIG. 3, the correction values (plus fixed divisor) applied to the dividers also need to be larger, therefore requiring more number of bits to represent the values and the paths on which they are provided.

As an example, the value on path 376 in FIG. 3 may be of the order of 500 (represented with an integer portion and a fractional portion). However, due to implementation of scaling block in the ‘direct correction’ path (here scaling block 440, as an example), the value on path 367 can be smaller by a factor (DIV3/DIV1), which can be a large number.

Hence, in the example, all of paths 367, 334, 323, block LPF 330 and PFD 320 can be implemented to process/handle values with smaller bit-widths (as compared to paths 376, 367, 334, 323 and blocks LPF 330 and PFD 320 of FIG. 3). Only, paths 443, 376, scaling block 440 and adder 370 will need to handle correspondingly larger bit-widths. Similar hardware-savings is also achieved with respect to CKT-3 due to implementation of scaling block 420 in the ‘direct correction’ path from node 167C to 176-2.

Several benefits of the design of a CMPLL as described herein are now briefly noted. Since only one VCO is employed, the total implementation area (e.g., when implemented in integrated circuit form) is relatively lower. All blocks other than the primary loop (and the oscillators) can be implemented in digital form and therefore in area as well as power-efficient manner. Due to the need for only one VCO, VCO 190 can implemented using LC circuits without concerns of spurious coupling between multiple LC-based VCOs. Undesired spurs in the spectrum of output clock 195 are also reduced in number and/or magnitude.

A CMPLL implemented as described above can be incorporated in a larger device or system as described briefly next.

### 6. System

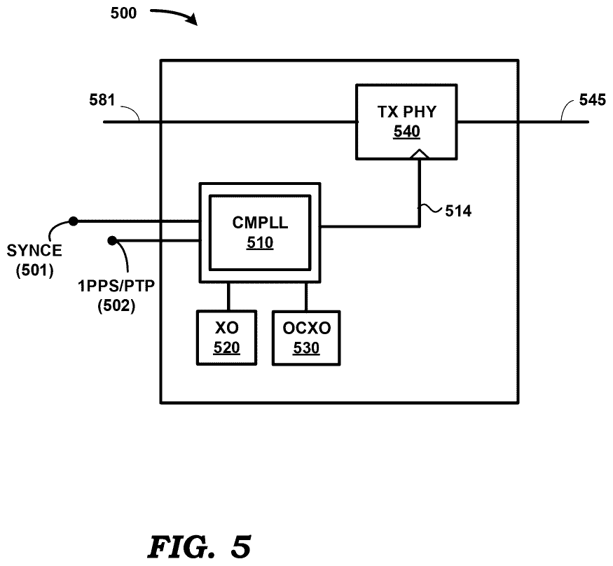

FIG. 5 is a block diagram of an example system containing a CMPLL implemented according to various aspects of the present disclosure, as described in detail above. System 500 is a line card, shown containing CMPLL 500, XO 520, OCXO 530 and PHY Transmitter 540. CMPLL 500 may be implemented as any of the CMPLLs described in detail above. Line card 500 may operate consistent with corresponding standards (e.g., International Telecommunications Unio (ITU) standards G. 8262.1 and G. 8273.2, and IEEE 1588) in packet networks. Line card 500 is used for re-timing data packets received over a network with respect to an available clock, and then transmitted in the physical layer. Line card 500 may be contained in a node (e.g., router) of a packet network.

Line card 500 receives a data packet on path 581, and forwards the packet on output path 545 after the packet has been re-timed (synchronized) with clock 514. The data packets may be generated by corresponding applications such as IPTV (Internet Protocol Television), VoIP (Voice over Internet Protocol), etc.

Clock 514 is generated by CMPLL 510 based on clocks generated by XO 520 (crystal oscillator), OCXO 530 (over-controlled crystal oscillator, SYNCE clock (501) and 1 -PPS/PTP clock (502). Clock 514 corresponds to output clock 195 (or clock 151) of any of the CMPLLs described above. CMPLL 510 is designed to operate consistent with the ITU-T standard G.8273.2, and supports the above-noted requirements (numbered 1 through 6 above) of the standard.

### 7. Conclusion

References throughout this specification to “one embodiment”, “an embodiment”, or similar language means that a particular feature, structure, or characteristic described in connection with the embodiment is included in at least one embodiment of the present disclosure. Thus, appearances of the phrases “in one embodiment”, “in an embodiment” and similar language throughout this specification may, but do not necessarily, all refer to the same embodiment.

While in the illustrations of FIGS. 1 through 5, although terminals/nodes are shown with direct connections to (i.e., “connected to”) various other terminals, it should be appreciated that additional components (as suited for the specific environment) may also be present in the path, and accordingly the connections may be viewed as being “electrically coupled” to the same connected terminals.

While various embodiments of the present disclosure have been described above, it should be understood that they have been presented by way of example only, and not limitation. Thus, the breadth and scope of the present disclosure should not be limited by any of the above-described embodiments, but should be defined only in accordance with the following claims and their equivalents.

What is claimed is:

1. A cascaded multi-loop phase-Locked Loop (CMPLL) comprising:
a plurality of loops containing a primary loop and a plurality of secondary loops according to a hierarchy, wherein said primary loop is highest in said hierarchy and each of the secondary loops is completed by components of loops higher in said hierarchy,
wherein each loop at a lower level provides a corresponding correction signal to correct any drift from a specification frequency of one or more loops at higher levels; and
a set of bypass circuits, wherein each bypass circuit is coupled between a first loop and a second loop located at least one skip-level higher in said hierarchy,
wherein the bypass circuit propagates a substitute signal as the corresponding correction signal from said first loop to said second loop when a loop at the skip-level is inoperative.

2. The CMPLL of claim 1, wherein said primary loop is an independent loop containing a frequency signal generator to generate an output clock, wherein said frequency signal generator is part of each of said plurality of loops.

3. The CMPLL of claim 2, wherein said loop at said skip-level being inoperative is due to loss of a source clock of said loop at said skip-level,
wherein said substitute signal is a scaled value of said correction signal.

4. The CPMLL of claim 3, wherein said at least one skip-level is one skip-level,
wherein said primary loop comprises a phase locked loop comprising:
a primary phase-frequency detector (PFD) to generate an first error signal representing a phase difference between a primary source clock and a first feedback clock;
a primary low-pass filter (LPF) to filter said first error signal to generate a first filtered error signal;
a controlled oscillator to generate an output clock with a frequency corresponding to a magnitude of said first filtered error signal; and
a primary frequency divider to divide a frequency of said output clock to generate said first feedback clock,
wherein a first one of said plurality of secondary loops comprises:
said primary frequency divider, said primary PFD, said primary LPF and said controlled oscillator;
a secondary phase-frequency detector (PFD) to generate a second error signal representing a phase difference between a secondary source clock and a second feedback clock;
a secondary low-pass filter (LPF) to filter said second error signal to generate a second filtered error signal; and
a secondary frequency divider to divide a frequency of said output clock to generate said second feedback clock,
wherein said second filtered error signal represents a correction value from said secondary loop, wherein a sum of said correction value and a fixed value is applied to set a divisor used by said primary frequency divider.

5. The CMPLL of claim 4, wherein each of the rest of the plurality of secondary loops comprises:
the secondary loop immediately higher in said hierarchy;
a respective (PFD) to generate a respective error signal representing a phase difference between a respective source clock and a respective feedback clock;
a respective low-pass filter (LPF) to filter said respective error signal to generate a respective filtered error signal; and
a respective frequency divider to divide a frequency of said output clock to generate said respective feedback clock,
wherein said respective filtered error signal represents a respective correction value from the corresponding one of the rest of the plurality of secondary loops,
wherein a sum of said respective correction value and a respective fixed value is applied to set a divisor used by the frequency divider of said secondary loop immediately higher in said hierarchy.

6. The CMPLL of claim 5, wherein a bypass circuit of said set comprises a scaling block to scale a correction value from said first loop, said scaling block to forward a scaled correction value as said substitute signal to said second loop, said scaled correction value being added to the filtered error signal of said loop at said skip-level.

7. The CMPLL of claim 6, wherein said correction value from said first loop is said respective filtered error signal of a corresponding one of said rest of the plurality of secondary loops,
wherein a scaling factor applied by said scaling block to scale said correction value equals a ratio of the fixed divisor of said second loop to the fixed divisor of said loop at said skip-level.

8. The CMPLL of claim 7, wherein said bypass circuit further comprises a low-pass filter (LPF) to filter said scaled respective error signal before forwarding to said first loop,
wherein said LPF is designed to have a same bandwidth as a bandwidth of said loop at said skip-level.

9. The CMPLL of claim 5, wherein said correction value from said first loop is said respective filtered error signal of a corresponding one of said rest of the plurality of secondary loops,
wherein a bypass circuit of said set comprises a low-pass filter (LPF) to filter said respective filtered error signal of said second loop to generate a final filtered error signal, and to forward said final filtered error signal to said first loop by adding said final filtered error signal to the filtered error signal of said loop at said skip-level,
wherein said LPF is designed to have a same bandwidth as a bandwidth of said loop at said skip-level.

10. The CMPLL of claim 9, wherein said each of the rest of the plurality of secondary loops further comprises:
a scaling block to scale a correction value from said first loop, said scaling block to forward a scaled correction value to said loop at said skip-level, said scaled correction value being added to a corresponding fixed value for the divisor of said respective frequency divider of said skip-level,
wherein a scaling factor applied by said scaling block equals a ratio of the fixed divisor of said second loop to the fixed divisor of the primary loop.

11. A system comprising:
a transmitter coupled to receive a first data packet, said line card to re-time said first data packet with reference to a re-timing clock, and to transmit a first re-timed packet; and
a cascaded multi-loop phase-Locked Loop (CMPLL) comprising:
a plurality of loops containing a primary loop and a plurality of secondary loops according to a hierarchy, wherein said primary loop is highest in said hierarchy and each of the secondary loops is completed by components of loops higher in said hierarchy,
wherein each loop at a lower level provides a corresponding correction signal to correct any drift from a specification frequency of one or more loops at higher levels; and
a set of bypass circuits, wherein each bypass circuit is coupled between a first loop and a second loop located at least one skip-level higher in said hierarchy,
wherein the bypass circuit propagates a substitute signal as the corresponding correction signal from said first loop to said second loop when a loop at the skip-level is inoperative.

12. The system of claim 11, wherein said primary loop is an independent loop containing a frequency signal generator to generate an output clock, wherein said frequency signal generator is part of each of said plurality of loops.

13. The system of claim 12, wherein said loop at said skip-level being inoperative is due to loss of a source clock of said loop at said skip-level,
wherein said substitute signal is a scaled value of said correction signal.

14. The system of claim 13, wherein said at least one skip-level is one skip-level,
wherein said primary loop comprises a phase locked loop comprising:
a primary phase-frequency detector (PFD) to generate a first error signal representing a phase difference between a primary source clock and a first feedback clock;
a primary low-pass filter (LPF) to filter said first error signal to generate a first filtered error signal;
a controlled oscillator to generate an output clock with a frequency corresponding to a magnitude of said first filtered error signal; and
a primary frequency divider to divide a frequency of said output clock to generate said first feedback clock,
wherein a first one of said plurality of secondary loops comprises:
said primary frequency divider, said primary PFD, said primary LPF and said controlled oscillator;
a secondary phase-frequency detector (PFD) to generate a second error signal representing a phase difference between a secondary source clock and a second feedback clock;
a secondary low-pass filter (LPF) to filter said second error signal to generate a second filtered error signal; and
a secondary frequency divider to divide a frequency of said output clock to generate said second feedback clock,
wherein said second filtered error signal represents a correction value from said secondary loop, wherein a sum of said correction value and a fixed value is applied to set a divisor used by said primary frequency divider.

15. The system of claim 14, wherein each of the rest of the plurality of secondary loops comprises:
the secondary loop immediately higher in said hierarchy;
a respective (PFD) to generate a respective error signal representing a phase difference between a respective source clock and a respective feedback clock;
a respective low-pass filter (LPF) to filter said respective error signal to generate a respective filtered error signal; and
a respective frequency divider to divide a frequency of said output clock to generate said respective feedback clock,
wherein said respective filtered error signal represents a respective correction value from the corresponding one of the rest of the plurality of secondary loops,
wherein a sum of said respective correction value and a respective fixed value is applied to set a divisor used by the frequency divider of said secondary loop immediately higher in said hierarchy.

16. The system of claim 15, wherein a bypass circuit of said set comprises a scaling block to scale a correction value from said first loop, said scaling block to forward a scaled correction value as said substitute signal to said second loop, said scaled correction value being added to the filtered error signal of said loop at said skip-level.

17. The system of claim 16, wherein said correction value from said first loop is said respective filtered error signal of a corresponding one of said rest of the plurality of secondary loops,
wherein said scaling block scales said respective filtered error signal by multiplying said respective filtered error signal by a scaling factor equal to the ratio of the fixed value corresponding to said first loop and the fixed value corresponding to said second loop,
wherein said bypass circuit further comprises a low-pass filter (LPF) to filter said scaled respective error signal before forwarding to said first loop,
wherein said LPF is designed to have a same bandwidth as a bandwidth of said loop at said skip-level.

18. The system of claim 15, wherein said correction value from said first loop is said respective filtered error signal of a corresponding one of said rest of the plurality of secondary loops,
wherein a bypass circuit of said set comprises a low-pass filter (LPF) to filter said respective filtered error signal of said second loop to generate a final filtered error signal, and to forward said final filtered error signal to said first loop by adding said final filtered error signal to the filtered error signal of said loop at said skip-level,
wherein said LPF is designed to have a same bandwidth as a bandwidth of said loop at said skip-level.

19. The system of claim 18, wherein said each of the rest of the plurality of secondary loops further comprises:
a scaling block to scale a correction value from said first loop, said scaling block to forward a scaled correction value to said loop at said skip-level, said scaled correction value being added to a corresponding fixed value for the divisor of said respective frequency divider of said skip-level,
wherein a scaling factor applied by said scaling block equals a ratio of the fixed divisor of said second loop to the fixed divisor of the primary loop.

20. The system of claim 19, wherein said plurality of secondary loops comprises three secondary loops, wherein a source clock of each of said three secondary loops respectively is a clock generated by an over-controlled crystal oscillator (OCXO), a SYNCE clock according to the Synchronous Ethernet standard and a one pulse-per-second clock obtained from the Global Positioning System (GPS) or Precision Time Protocol (PTP).
